(19) United States
(12) Patent Application Publication
(10) Pub. No.: US 2013/0074935 A1
(43) Pub. Date: Mar. 28, 2013

(54) DYE FORMULATION FOR FABRICATING DYE SENSITIZED ELECTRONIC DEVICES

(71) Applicants: John C. Warner, Wilmington, MA (US); Michael S. Viola, Burlington, MA (US)

(72) Inventors: John C. Warner, Wilmington, MA (US); Michael S. Viola, Burlington, MA (US)

(73) Assignee: WARNER BABCOCK INSTITUTE FOR GREEN CHEMISTRY, Wilmington, MA (US)

(21) Appl. No.: 13/224,524

(22) Filed: Sep. 23, 2011

(51) Int. Cl. H01L 51/44; H01L 51/48; C09B 67/40; H01L 51/46

(52) U.S. Cl. 136/263; 257/40; 438/82; 8/609; 8/581; 8/552; 8/561; 8/611; 257/E51.012; 257/E51.026

(57) ABSTRACT

Disclosed and claimed herein is an aqueous dye dispersion for making a dye sensitized electronic device having, a water insoluble dye, an alkalizing agent, a surfactant; and water. The water insoluble dye has at least one acid group and the aqueous dye dispersion is substantially free of volatile organic solvents, co-solvents and diluents. Further disclosed and claimed is a method of making a photoelectronic device using the claimed aqueous dye dispersion.

### FIELD OF THE INVENTION

The present invention is in the field of material compositions used to assemble dye sensitized solar cells (DSSC) and other dye sensitized electronic devices such as information storage devices, sensing devices and imaging devices. In particular, it concerns the utility of applying highly absorbing organic chromophores from aqueous dispersions so that they function as sensitizers in dye sensitized electronic devices.

### BACKGROUND

Sensitization of semiconductor solids such as metal oxides in imaging devices, memories, sensors and solar cells can serve as an effective means of energy transduction. These devices use metal oxides, such as titanium dioxide that are transparent to light but can be sensitized to the desired spectrum through the use of sensitizing agents that absorb light energy and transduce it into electrical power or an electrical signal. This sensitization occurs through charge injection into the metal oxide from the excited state of the dye sensitizer. Sensitizers such as transition metal complexes, inorganic colloids and organic dye molecules are used.

Prominent among such technologies is the dye-sensitized metal oxide solar cell (DSSC). DSSCs use a dye to absorb light and initiate a rapid electron transfer to a nanostructured oxide such as anatase TiO₂. The mesoscopic structure of the TiO₂ allows building of thick, nanoporous films with active-layer thicknesses of several microns. The dye is then adsorbed on the large surface area of the TiO₂. Charge balance and transport is achieved by a layer having a REDOX couple, such as iodide/triiodide (I⁻/I₃⁻.

Dyes based on transition metal complexes are disclosed in Grätzel et al., U.S. Pat. Nos. 4,927,721 and 5,350,644. These dye materials are disposed on mesoporous metal oxides that have a high surface area on which the absorbing, sensitizing layer can be formed. This results in a high absorptivity of light in the cell. Dyes such as Ru(II) (2,2′-bipyridyl 4,4′ dicarboxylate)₂(NCS)₂ have been found to be efficient sensitizers and can be attached to the metal oxide solid through carboxyl or phosphonate groups on the periphery of the compounds. However, when transition metal ruthenium complexes are used as sensitizers they must be applied to the mesoporous metal oxide layers in a coat as thick as 10 micrometers or thicker in order to absorb enough solar radiation to attain sufficient power conversion efficiencies. Further, the ruthenium complexes are expensive. In addition, such dyes must be applied using volatile organic solvents, co-solvents and diluents because they are not dispersible in water. Volatile organic compounds (VOCs) are significant pollutants that can affect the environment and human health. While VOCs are usually not acutely toxic, they may have chronic health and environmental effects. For this reason, governments around the world are seeking to reduce the levels of VOCs.

It would therefore be desirable to minimize the cost of the dye formulation and to provide formulations for processing dye sensitized electronic devices that are substantially free of volatile organic solvents, co-solvents and diluents.

### DETAILED DESCRIPTION

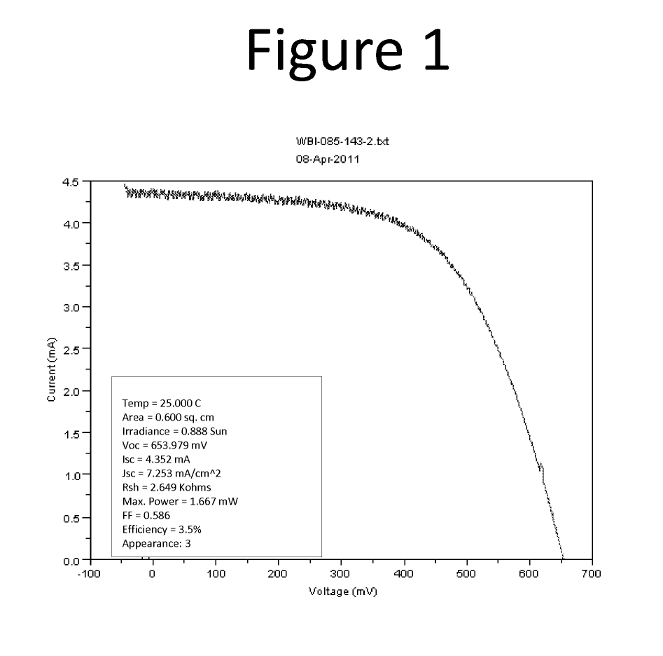

FIG. 1 shows a spectrum of 1.6×10⁻⁴ M (Z)-3-(4-(4-(bis(4-tert-butylphenyl)amino)styryl)-2,5-dimethoxyphenyl)-2-cyanoacrylic acid (BASCA) in ethanol solution in the visible wavelength region.

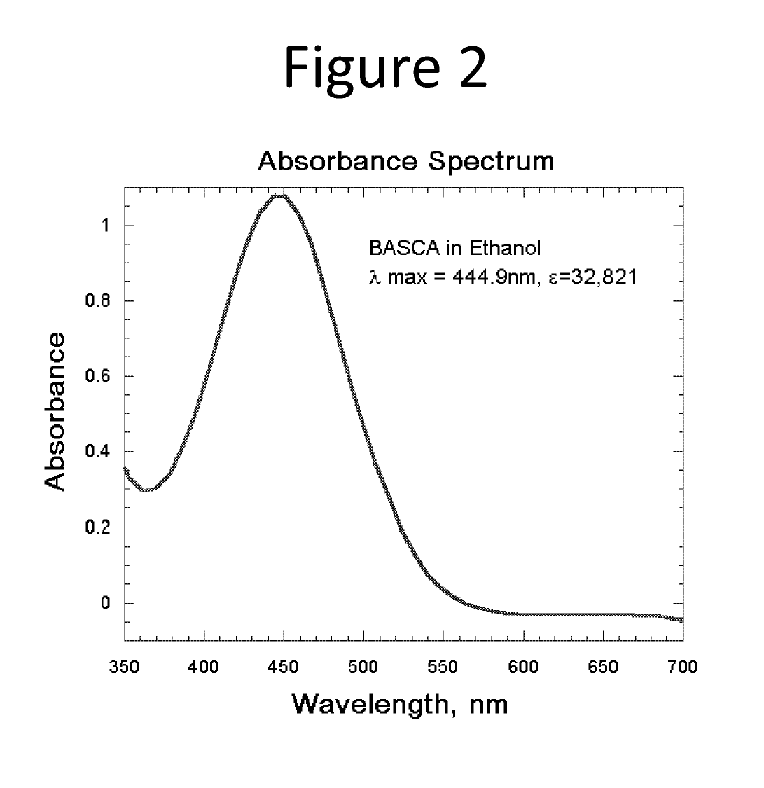

FIG. 2 shows a spectrum of 1.6×10⁻⁴ M (BASCA) in an aqueous dispersion in the visible wavelength region; which solution includes 0.05M ammonia and 0.5 wt % Triton-X-100° surfactant.

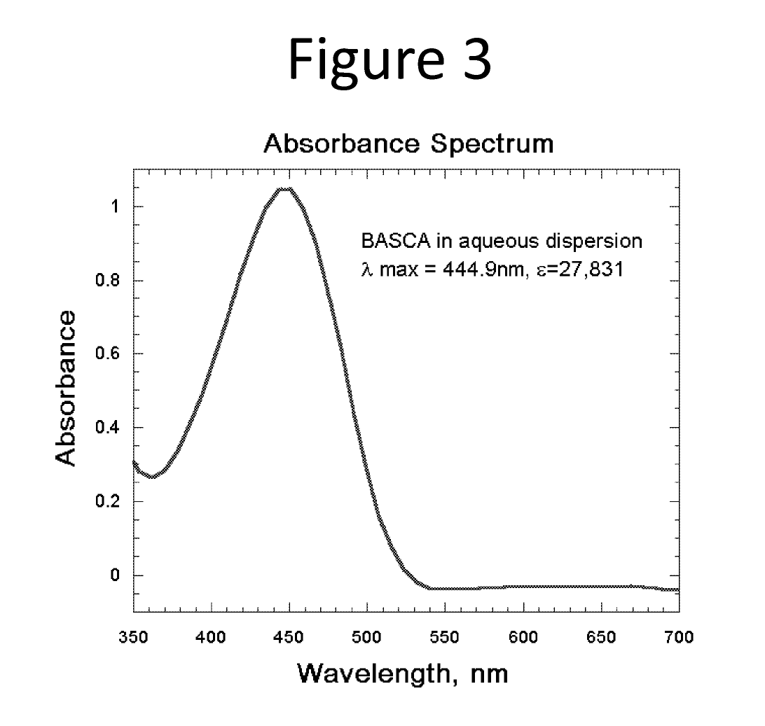

FIG. 3. shows a photocurrent spectrum obtained from electronic devices wherein the mesoporous TiO₂ is coated with the aqueous dye dispersion described and claimed herein.

As used herein, the conjunction “or” is not intended to be exclusive unless otherwise noted. For example, the phrase “or alternatively” is intended to be exclusive. Further, when used in connection with chemical substitution at a specific position, the conjunction “or” is intended to be exclusive. As used herein, the adjective “exemplary” is used simply to point to an example and is not meant to indicate preference. As used herein, the term “dispersion” includes solutions, colloidal suspensions, emulsions, microemulsions, sols and the like; such that a dye material, for example, is said to be dispersed in a liquid medium such as water. As used herein, mesoporous materials are porous materials with pores of about 2 to about 100 nm in size. As used herein, the term “volatile organic compound” (VOC) means any compound containing at least one atom of carbon, excluding carbon monoxide, carbon dioxide, carbonic acid, metallic carbides or carbonates, and ammonium carbonate, whose and boiling point is less than 250° C. Some volatile organic compounds include organic solvents, co-solvents and diluents, subject to the above definition. As used herein, a solvent is understood to be a material that forms a solution with a solid or liquid solute. As used herein, a co-solvent is understood to be a material that, in conjunction with a solvent or another co-solvent, forms a solution with a solid or liquid solute. As used herein, a diluent is understood to be a filler, thinner or dispersing agent, used alone or in conjunction with a solvent and/or co-solvent. Organic compounds such as the dyes disclosed herein, may be synthesized in various solvents, co-solvents and diluents and under various conditions. Accordingly, there may be residual solvents, co-solvents and diluents present as contaminants. Herein, the term “substantially free of” in reference to solvents, co-solvents and diluents, is intended to mean less than about 2% w/w of the aqueous dye dispersion.

In a first embodiment, the present application for patent discloses and claims an aqueous dye dispersion for making a dye sensitized electronic device. The formulation includes a water insoluble dye; an alkalizing agent; a surfactant; and water. In this embodiment the water insoluble dye comprises at least one acid group and the aqueous dye dispersion is substantially free of volatile organic solvents, co-solvents and diluents.

In a second embodiment, the present application for patent discloses and claims a method of making a dye sensitized electronic device, comprising: providing the aqueous dye dispersion described supra, providing a substrate with a metal oxide disposed on the substrate; forming a coating on the metal oxide using the aqueous dye dispersion so that a dye sensitized metal oxide is formed.

Dyes used in dye sensitized electronic devices should have substantial absorbance in the wavelength of interest. For example, in dye sensitized solar cells, the dye should have absorbance at wavelengths between about 400 nm and about 1000 nm. Thin film spectra can differ from solution spectra in several respects. First, in dilute solution, dyes tend not to associate with other dye molecules. Rather, they associate with solvent molecules that may cause a small shift in the measured spectrum. On the other hand, in thin film spectra, dye molecules can associate in such a way as to exhibit an entirely different spectrum from that seen in solution.

We have found, unexpectedly, that a water dispersion of a dye can be used effectively to sensitize an electronic device such as a dye sensitized solar cell, an imaging device or an optical information storage device. The process, outlined infra, includes coating a mesoporous metal oxide with the aqueous dye dispersion and baked at easily obtainable temperatures.

Various exemplary acid groups can be placed on the dye molecule. These include one or more carboxylic acids, sulfonic acids, phosphonic acids, phenol groups and α,α′-methylene dicarbonyl groups or combinations thereof. The acid groups can have pKa values in water between about −3 to about 11. In addition, combinations of acid groups can be placed on the dye molecule.

Various exemplary alkalizing agents can be used. These include, without limitation, alkali metal carbonates and bicarbonates, amines, alkaline earth metal carbonates and bicarbonates, amines, pyridinic groups, indoles, imidazoles and the like. Further, ammonia, ammonium carbonate and ammonium bicarbonate can be used as well as mixtures of any of the above.

Various exemplary nonionic surfactants can be used in connection with the formulation disclosed and claimed herein. These include polyglycerol ethers; polyoxyethylenated (C₈-C₁₈) alcohols; polyoxyethylenated (C₅-C₂₀) alkyl phenols; (C₈-C₁₈)-alkyl (poly) glycosides; polyoxyethyleneated C₁₀-C₂₀ fatty acids; or polyoxyethyleneated siloxanes, and block copolymers of polyethylene oxide and polypropylene oxide, wherein the polyethylene oxide and polypropylene oxide portions are terminated by H, OH or O(C₁-C₅) alkyl. Other suitable surfactants include alkyl ethoxylated phenols, such as octyl and nonyl ethoxylated phenols, including, for example, the Triton and Tergitol series of surfactants.

Various exemplary amphoteric surfactants can also be used in connection with the formulation disclosed and claimed herein. These include, without limitation, N-alkyl beta-alanines, betaines, amino betaines, amido betaines, imidazoline betaines, amino oxides, as well as mixtures thereof.

Without limitation, an exemplary class of dyes is described and claimed herein This class of dyes is denoted by the following structure:

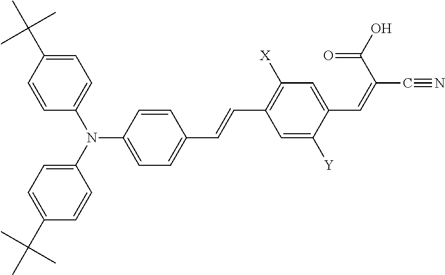

wherein the dye is where X and Y can be the same or different and are chosen from the groups —OR₁ or —R₂; where R₁ and R₂ can be the same or different and are H, (C₁-C₂₀) alkyl, or (CH₂)_{Z}COOH; and Z is 1-20.

Various dye sensitized electronic devices employ charge transport layers to facilitate the transduction of charge either from back into the dye sensitized layer. Charge transport layers comprise an electrolyte and/or a REDOX couple. Without limitation, exemplary REDOX couples can be chosen from I₃⁻/I⁻, Co⁺⁺⁺/Co⁺⁺, Fe⁺⁺⁺/Fe⁺⁺, Cu⁺⁺/Cu⁺, Ag⁺/Ag, ferrocinium/ferrocene, tetrazoles/disulphides and combinations thereof.

In connection with the devices disclosed and claimed herein, various metal oxides can be used. Without limitation, the metal oxides may or may not be mesoporous materials. Without limitation, metal oxides can include titanium dioxide, tungsten trioxide, tin dioxide, zinc oxide, strontium titanate, niobium monoxide and niobium pentoxide.

Various devices are disclosed and claimed herein. An exemplary device is a dye sensitized solar cell (DSSC). The instant device includes: a substrate; a conductor or semiconductor disposed on the substrate; a metal oxide layer disposed on the conductor or semiconductor, wherein the metal oxide layer may or may not be a mesoporous material and the metal oxide layer may be doped; an organic dye layer disposed on the mesoporous metal oxide layer; wherein the organic dye layer is made from the aqueous dye dispersion described herein; a charge transport layer in contact with the organic dye layer; wherein the charge transport layer is described supra; and a second conductor in electrical contact with the charge transport layer.

Further exemplary is an imaging device having a plurality of individual cells, wherein each cell includes: a substrate; a conductor or semiconductor disposed on the substrate; a metal oxide layer disposed on the conductor or semiconductor, wherein the metal oxide layer may or may not be a mesoporous material and the metal oxide layer may be doped; an organic dye layer disposed on the mesoporous metal oxide layer; wherein the organic dye layer is made from the aqueous dye dispersion described herein; a charge transport layer in contact with the organic dye layer; wherein the charge transport layer is described supra; and a second conductor in electrical contact with the charge transport layer; wherein the second conductor is transparent; a second substrate; wherein the second substrate is transparent; and a color filter, selected to be transparent at the wavelength of interest.

Further exemplary is an optical information storage device having a plurality of individual cells, wherein each cell includes: a substrate; a conductor or semiconductor disposed on the substrate; a metal oxide layer disposed on the conductor or semiconductor, wherein the metal oxide layer may or may not be a mesoporous material and the metal oxide layer may be doped; an organic dye layer disposed on the mesoporous metal oxide layer; wherein the organic dye layer is made from the aqueous dye dispersion described herein; a charge transport layer in contact with the organic dye layer; wherein the charge transport layer is described supra; and a second conductor in electrical contact with the charge transport layer; wherein the second conductor is transparent; a second substrate; wherein the second substrate is transparent; and a capacitor wired to either the first conductor or the second conductor. The capacitor can also include a floating electrode tunneling device in which a conductor is isolated between insolating dielectrics. To address each memory cell in the array, addressing electronics known in the art can be used. To read the charge condition on the capacitor of each memory element in the array, sensing amplifiers known in the art can be used. Also known in the art are design strategies to avoid the formation of “sneak paths” between different elements of the memory array using additional transistors or diodes.

### EXAMPLES

Materials used in these examples were obtained from Aldrich Chemical Co. unless otherwise indicated. Percentages are wt/wt unless otherwise noted.

### Example 1

### Preparation of (Z)-3-(4-(4-(bis(4-tert-butylphenyl)amino)styryl)-2,5-dimethoxyphenyl)-2-cyanoacrylic acid

Tris(dibenzylideneacetone)dipalladium(0) (Pd₂(dba)₃) (0.765 g, 0.83 mmol) and Sodium tert-butoxide (NaOtBu) (14.11 g, 146.81 mmol) were combined in a round bottom flask, that had been flushed with N₂. To this was added 1-bromo-4-tert-butylbenzene (17.88 g, 83.89 mmol), 4-amino styrene (5.00 g, 41.95 mmol), phosphine (0.57 g, 1.66 mmol) and toluene (125.00 ml). The reaction was heated to 85° C. for 3.5 hours before cooling to room temperature. The mixture was then filtered to remove the inorganic salts and washed with methylene chloride. The methylene chloride/toluene solvents were removed under reduced pressure to give a dark brown residue. The organic residue was then taken up in methylene chloride and washed with saturated brine. The organic layer was dried over magnesium sulfate, filtered and separated using a Teledyne ISCO gold column, using methylene chloride and hexanes to elute. ¹H and ¹³C confirmed the formation of the desired compound. Recovered 13.84 g as a white solid. (86% yield). An absorbance spectrum of the instant compound dissolved in ethanol is shown in FIG. 1.

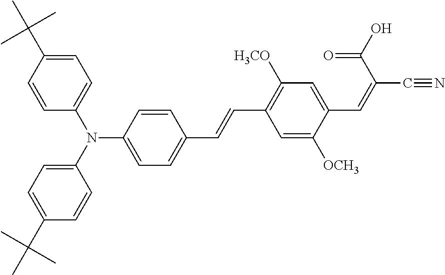 [SMILES: COc1cc(/C=C/c2ccc(N(c3ccc(C(C)(C)C)cc3)c3ccc(C(C)(C)C)cc3)cc2)c(OC)cc1/C=C(/C#N)C(=O)O]

### Example 2

In a test tube were combined 15 mg (24.4 micromole) of (Z)-3-(4-(4-(bis(4-tert-butylphenyl)amino)styryl)-2,5-dimethoxyphenyl)-2-cyanoacrylic acid, (BASCA), 0.88 g water, 750 microliters of a 2% Triton-X-100® (hereinafter, TX-100) solution and 0.3 ml of a 5M NH₃ solution. A dark, stable dye dispersion was obtained.

### Examples 3-18

Similar to Example 2 except that the loadings of the dye, surfactant, water and ammonia were varied as shown in Table 1. Results are as indicated. Among these compositions, the Examples shown as having been “Dispersed” appeared to be taken up into the aqueous medium with no settling. Examples 4, 6 and 13 appeared to be dispersed as true solutions. Examples labeled “Not completely dispersed—some settling” exhibited some coloration of the aqueous medium but also exhibited settling. The composition of Example 4 was used to construct an exemplary dye sensitized solar cell. An absorbance spectrum similar to the composition of Example 4 but further diluted so as to be roughly in the spectroscopic analytical range is shown in FIG. 3.

TABLE 1

| | | | Amount of | Amount of | |
|---|---|---|---|---|---|
| Exam- | Amount of | Amount of | 2 wt % | 5M | |
| ple | dye, mg | water, g | TX-100, g | NH₃, g | Appearance |
| 3 | 15 | 2.53 | 0.15 | 0.30 | Dispersed |
| 4 | 15 | 1.93 | 0.75 | 0.30 | Dispersed - |
| | | | | | soluble |
| 5 | 15 | 1.03 | 0.15 | 1.80 | Dispersed |
| 6 | 15 | 0.43 | 0.75 | 1.80 | Dispersed - |
| | | | | | soluble |
| | | | | | Not completely |
| 7 | 60 | 2.49 | 0.15 | 0.30 | dispersed - |
| | | | | | some settling |
| | | | | | Not completely |
| 8 | 60 | 1.89 | 0.75 | 0.30 | dispersed - |
| | | | | | some settling |
| 9 | 60 | 0.99 | 0.15 | 1.80 | Dispersed |
| 10 | 60 | 0.39 | 0.75 | 1.80 | Dispersed |
| 11 | 37.5 | 1.46 | 0.45 | 1.05 | Dispersed |
| 12 | 37.5 | 1.46 | 0.45 | 1.05 | Dispersed |
| 13 | 15 | 1.48 | 0.45 | 1.05 | Dispersed - |
| | | | | | soluble |
| 14 | 60 | 1.44 | 0.45 | 1.05 | Not completely |
| | | | | | dispersed - |
| | | | | | some settling |
| 15 | 37.5 | 2.21 | 0.45 | 0.30 | Dispersed |
| 16 | 37.5 | 0.71 | 0.45 | 1.80 | Dispersed |
| 17 | 37.5 | 1.76 | 0.15 | 1.05 | Dispersed |
| 18 | 37.5 | 1.16 | 0.75 | 1.05 | Dispersed |

### Example 19

A 2 inch by 2 inch piece of fluorine doped tin oxide (FTO) treated glass (obtained from Hartford glass Co., Hartford, Ind.) was coated with a titanium dioxide semiconductor layer (D20, 12% solids, obtained from Solaronix, Switzerland) by using 2 strips of tape of double thickness (3M, 50 microns thick, hence 100 microns overall thickness) spaced 1 cm apart and coating the fluid into the space between the tapes. The coating was dried at room temperature and then heated at 100 C for 20 minutes to further dry it. After drying, the tape was removed and the dried coating was trimmed to 1 cm×1 cm square. This coating was then further treated by sintering at 450° C. for 30 minutes.

After cooling, the semiconductor layer was dyed using a ‘staining’ method. 60 ul of the solution obtained from Example 4, supra, described in example 3 was applied to the semiconductor layer and then allowed to dry. 1 more application (60 ul) of the fluid was made resulting in an intensely colored dark orange semiconductor. After drying at room temperature any excess dye was rinsed off by using ethanol.

Assembly of the cell: Another piece of 2 in×2 in FTO treated glass was washed with ethanol and was then ‘painted’ with Platisol (obtained from Solaronix, Switzerland), dried at room temperature and then baked at 450 C. for 30 minutes. 2 small holes (˜2 mm) were drilled into this piece of glass on the opposite side of the semiconductor and this piece of glass was then heat laminated to the semiconductor prepared glass using a piece of adhesive film (Meltonix, obtained from Solaronix, Switzerland) cut into the shape of a rectangle and used as a ‘well’ to hold the electrolyte. Lamination was done using clamps and holding the pieces of glass together for 30 minutes @ 150° C.

After assembly the cell was filled with electrolyte (Iodolyte, obtained from Solarorinx) through one of the filling holes drilled earlier. Both holes were then sealed with the thermal adhesive film.

The resulting cell was placed in a solar simulator and illuminated with 1 Kw/m² intensity. A current vs. voltage curve was generated and readings the resulting IV curve is shown in FIG. 3 and the following data were obtained:

TABLE 2

| Open circuit voltage | 654 mV |
|---|---|
| Short circuit current | 4.35 mA |
| Fill Factor | 0.586 |
| Corrected efficiency | 3.5% |

The present invention has been described in connection with various embodiments. Notwithstanding the foregoing, it should be understood that modifications, alterations, and additions can be made to the invention without departing from the scope of the invention as defined by the appended claims.

We claim:

1. An aqueous dye dispersion for making a dye sensitized electronic device, comprising:
a. a water insoluble dye;
b. an alkalizing agent;
c. a surfactant; and
d. water;
wherein the water insoluble dye comprises at least one acid group and wherein the aqueous dye dispersion is substantially free of volatile organic solvents, co-solvents and diluents.

2. The aqueous dye dispersion of claim 1, wherein the at least one acid group is chosen from a carboxylic acid, a sulfonic acid, a phosphonic acid, a phenol or an α,α′-methylene dicarbonyl group or combinations thereof.

3. The aqueous dye dispersion of claim 1, wherein the at least one acid group comprises a plurality of acid groups that are the same or different, and wherein the acid groups are chosen from a carboxylic acid, a sulfonic acid, a phosphonic acid, a phenol or an α,α′-methylene dicarbonyl group or combinations thereof.

4. The aqueous dye dispersion of claim 1, wherein the alkalizing agent is chosen from ammonia, ammonium carbonate, ammonium bicarbonate or mixtures thereof.

5. The aqueous dye dispersion of claim 1, wherein the surfactant is a nonionic surfactant chosen from a polyglycerol ether; a polyoxyethylenated (C₈-C₁₈) alcohol; a polyoxyethylenated (C₅-C₂₀) alkyl phenol; a (C₈-C₁₈)-alkyl (poly) glycoside; a polyoxyethyleneated C₁₀-C₂₀ fatty acid; or a polyoxyethyleneated siloxane, a block copolymer of polyethylene oxide and polypropylene oxide; wherein the polyethylene oxide and polypropylene oxide portions are terminated by H, OH or O(C₁-C₅) alkyl.

6. The aqueous dye dispersion of claim 1, wherein the dye is 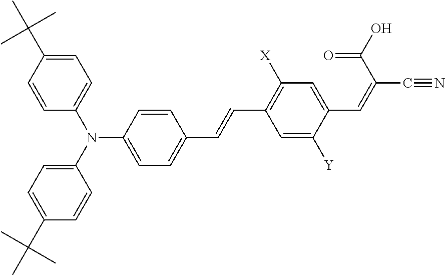
where X and Y can be the same or different and are chosen from the groups —OR₁ or —R₂; where R₁ and R₂ can be the same or different and are H, (C₁-C₂₀) alkyl, or (CH₂)_{Z}COOH; and Z is 1-20.

7. A dye sensitized solar cell comprising:
a. a substrate;
b. a conductor or semiconductor disposed on the substrate;
c. a mesoporous metal oxide layer disposed on the conductor or semiconductor;
d. an organic dye layer disposed on the mesoporous metal oxide layer; wherein the organic dye layer is made from the aqueous dye dispersion of claim 1;
e. a charge transport layer in contact with the organic dye layer; wherein the charge transport layer comprises a REDOX couple chosen from I₃⁻/I⁻, Co⁺⁺⁺/Co⁺⁺, Fe⁺⁺⁺/Fe⁺⁺, Cu⁺⁺/Cu⁺, Ag⁺/Ag, ferrocinium/ferrocene or combinations thereof
f. a second conductor in electrical contact with the charge transport layer.

8. An imaging device comprising an array of individually addressable cells, each cell comprising:
a. a first substrate;
b. a conductor or semiconductor disposed on the first substrate;
c. a mesoporous metal oxide layer disposed on the conductor or semiconductor;
d. an organic dye layer disposed on the mesoporous metal oxide layer; wherein the organic dye layer is made from the aqueous dye dispersion of claim 1;
e. a charge transport layer in contact with the organic dye layer; wherein the charge transport layer comprises a REDOX couple chosen from I₃⁻/I⁻, Co⁺⁺⁺/Co⁺⁺, Fe⁺⁺⁺/Fe⁺⁺, Cu⁺⁺/Cu⁺, Ag⁺/Ag, ferrocinium/ferrocene, or combinations thereof
f. a second conductor in electrical contact with the charge transport layer; wherein the second conductor is transparent;
g. a second substrate; wherein the second substrate is transparent; and
h. a color filter, selected to be transparent at the wavelength of interest.

9. An information storage device an array of individually addressable cells, each cell comprising:
a. a first substrate;
b. a conductor or semiconductor disposed on the first substrate;
c. a mesoporous metal oxide layer disposed on the conductor or semiconductor;
d. an organic dye layer disposed on the mesoporous metal oxide layer; wherein the organic dye layer is made from the aqueous dye dispersion of claim 1;
e. a charge transport layer in contact with the organic dye layer; wherein the charge transport layer comprises a REDOX couple chosen from I₃⁻/I⁻, Co⁺⁺⁺/Co⁺⁺, Fe⁺⁺⁺/Fe⁺⁺, Cu⁺⁺/Cu⁺, Ag⁺/Ag, ferrocinium/ferrocene, or combinations thereof
f. a second conductor in electrical contact with the charge transport layer; wherein the second conductor is transparent;
g. a second substrate; wherein the second substrate is transparent; and
h. a capacitor electrically connected to the first conductor or, alternatively the second conductor.

10. A method of making a dye sensitized electronic device, comprising:
a. providing an aqueous dye dispersion comprising
i. a water insoluble dye;
ii. an alkalizing agent;
iii. a surfactant; and
iv. water;
wherein the water insoluble dye comprises at least one acid group and wherein the aqueous dye dispersion is substantially free of volatile organic solvents, co-solvents and diluents;
b. providing a composite comprising a metal oxide layer;
c. forming a coating on the metal oxide layer from the aqueous dye dispersion whereby a dye sensitized metal oxide is formed.

11. The method of claim 7, further comprising contacting the dye sensitized metal oxide with a charge transport layer.

12. The method of claim 8 wherein the charge transport layer comprises a REDOX couple chosen from I₃⁻/I⁻, Co⁺⁺⁺/Co⁺⁺, Fe⁺⁺⁺/Fe⁺⁺, Cu⁺⁺/Cu⁺, Ag⁺/Ag, ferrocinium/ferrocene, or combinations thereof.

13. The method of claim 7 wherein the metal oxide is a mesoporous material

14. The method of claim 7, wherein the metal oxide comprises titanium dioxide, tungsten trioxide, tin dioxide, zinc oxide, strontium titanate, niobium monoxide and niobium pentoxide.

15. The method of claim 7 wherein the composite further comprises a conductor or a semiconductor.

16. The method of claim 7, wherein the at least one acid group is chosen from a carboxylic acid, a sulfonic acid, a phosphonic acid, a phenol or an α,α′-methylene dicarbonyl group or combinations thereof.

17. The method of claim 7, wherein the at least one acid group comprises a plurality of acid groups that are the same or different, and wherein the acid groups are chosen from a carboxylic acid, a sulfonic acid, a phosphonic acid, a phenol or an α,α′-methylene dicarbonyl group or combinations thereof.

18. The method of claim 7, wherein the alkalizing agent is chosen from ammonia, ammonium carbonate, ammonium bicarbonate or mixtures thereof.

19. The method of claim 7, wherein the surfactant is a nonionic surfactant chosen from a polyglycerol ether; a polyoxyethylenated (C₈-C₁₈) alcohol; a polyoxyethylenated (C₅-C₂₀) alkyl phenol; a (C₈-C₁₈)-alkyl (poly) glycoside; a polyoxyethyleneated C₁₀-C₂₀ fatty acid; or a polyoxyethyleneated siloxane, a block copolymer of polyethylene oxide and polypropylene oxide; wherein the polyethylene oxide and polypropylene oxide portions are terminated by H, OH or O(C₁-C₅) alkyl.

20. The method of claim 7, wherein the dye is 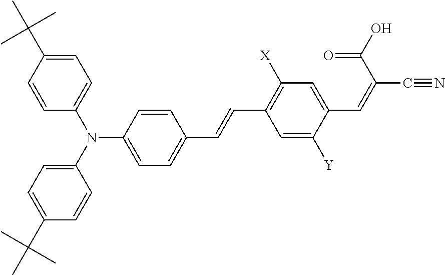
where X and Y can be the same or different and are chosen from the groups —OR₁ or —R₂; where R₁ and R₂ can be the same or different and are H, (C₁-C₂₀) alkyl, or (CH₂)_{Z}COOH; and Z is 1-20.
